(19) United States
(12) Patent Application Publication
(10) Pub. No.: US 2008/0179636 A1
(43) Pub. Date: Jul. 31, 2008

(54) N-FETS WITH TENSILELY STRAINED SEMICONDUCTOR CHANNELS, AND METHOD FOR FABRICATING SAME USING BURIED PSEUDOMORPHIC LAYERS

(75) Inventors: Dureseti Chidambarrao, Weston, CT (US); Effendi Leobandung, Wappingers Falls, NY (US); Anda C. Mocuta, LaGrangeville, NY (US); Dan M. Mocuta, LaGrangeville, NY (US); David M. Onsongo, Newburgh, NY (US); Carl J. Radens, LaGrangeville, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/307,224

(22) Filed: Jan. 27, 2007

(51) Int. Cl. H01L 29/04; H01L 21/335; H01L 21/8238

(52) U.S. Cl. 257/255; 438/150; 438/198; 257/E29.003; 257/E29.242; 257/E21.633; 257/E21.64; 257/E21.704

(57) ABSTRACT

The present invention relates to high performance n-channel field effect transistors (n-FETs) that each contains a strained semiconductor channel, and methods for forming such n-FETs by using buried pseudomorphic layers that contain pseudomorphically generated compressive strain.

### FIELD OF THE INVENTION

This invention relates to semiconductor devices containing high performance field effect transistors (FETs). More specifically, the present invention relates to semiconductor devices containing at least one high performance n-channel FEF (n-FET) that contains a strained semiconductor channel, and methods for forming such an n-FET using a buried pseudomorphic layer that contains pseudomorphically generated compressive strain. The present invention also relates to semiconductor devices that contain at least one of the above-described high performance n-FET with at least one adjacent p-channel FET (p-FET), which contains a semiconductor channel substantially free of strain, and methods for fabricating the n-FET and the p-FET via an integrated complementary metal-oxide-semiconductor (CMOS) process.

### BACKGROUND OF THE INVENTION

Improving the overall performance of CMOS devices by scaling is becoming increasingly difficult, so it has recently been proposed to improve the CMOS device performance by improving the carrier mobility instead.

It has been discovered that mechanical strains within a semiconductor device substrate can be used to modulate carrier mobility in the CMOS devices and improve device performance. For example, in silicon, hole mobility is enhanced when the silicon film is under compressive strain in the silicon film direction and/or under tensile strain in a direction normal of the silicon film, while the electron mobility is enhanced when the silicon film is under tensile strain in the film direction and/or under compressive strain in the direction normal of the silicon film. Therefore, compressive and/or tensile strains can be advantageously created in the channel regions of a p-channel metal-oxide-semiconductor field effect transistor (p-MOSFET) and/or an n-channel metal-oxide-semiconductor field effect transistor (n-MOSFET) in order to enhance the performance of such devices.

Various methods have been employed for applying the desired mechanical strains to the CMOS devices. For example, some of these methods involve process-induced strain, while others involve the use of strained film substrates.

There is still a continuing need for improved methods of applying desired strains to the CMOS devices.

### SUMMARY OF THE INVENTION

The present invention proposes a new method for creating desired tensile strain in the channels of n-type field effect transistors (n-FETs).

In one aspect, the present invention relates to a method for fabricating a semiconductor device that comprises at least one n-channel field effect transistor (n-FET), said method comprising:

forming a pseudomorphic layer over a semiconductor substrate, wherein the pseudomorphic layer has a lattice constant sufficiently larger than that of the semiconductor substrate to create compressive strain therein;
forming a semiconductor channel layer over the pseudomorphic layer;
forming a gate stack over the semiconductor channel layer;
patterning a portion of the semiconductor channel layer and the pseudomorphic layer using the gate stack as a mask to form at least one mesa structure, in which the compressively strained pseudomorphic layer is at least partially relaxed to cause tensile strain in the semiconductor channel layer located thereabove; and
epitaxially growing first and second semiconductor structures at opposite sides of the mesa structure to form an n-FET that contains a source and a drain formed by the first and second semiconductor structures and a channel formed by the tensilely strained semiconductor channel layer in the mesa structure.

Preferably, the mesa structure is characterized by a lateral half-width ranging from about 5 nm to about 1 μm. The thickness of the semiconductor channel layer preferably ranges from about 50 Å to about 150 Å, and more preferably from about 80 Å to about 120 Å.

Preferably, but not necessarily, the semiconductor substrate comprises silicon, while the pseudomorphic layer comprises SiGe.

Further, at least one p-channel field effect transistor (p-FET) is preferably formed adjacent to the n-FET by the method of the present invention.

In one embodiment of the present invention, the semiconductor channel layer and the pseudomorphic layer do not extend into the p-FET. Specifically, the p-FET comprises a source, a drain, and a channel that are all located in the semiconductor substrate with a gate stack located on the channel. The channel of such a p-FET is essentially free of tensile strain.

In an alternative embodiment of the present invention, the semiconductor channel layer and the pseudomorphic layer extend into the p-FET. Specifically, the p-FET comprises a channel that is formed by an un-patterned and continuous portion of the semiconductor channel layer, with a raised source and drain located on the semiconductor channel layer at opposite sides of the channel and a gate stack located on the channel.

Another aspect of the present invention relates to a method for fabricating a semiconductor device that comprises at least one n-channel field effect transistor (n-FET), said method comprising:

forming a pseudomorphic layer over a semiconductor substrate, wherein the pseudomorphic layer has a lattice constant sufficiently larger than that of the semiconductor substrate to create compressive strain therein;
forming a semiconductor channel layer over the pseudomorphic layer;
forming a gate stack over the semiconductor channel layer;
epitaxially growing first and second semiconductor structures at opposite sides of the gate stack;
removing the one or more sidewall spacers from the gate stack;
introducing amorphization implants into the semiconductor channel layer and the pseudomorphic layer through openings formed by removal of the sidewall spacers, wherein the amorphization implants break continuity of the semiconductor channel layer and the pseudomorphic layer to at least partially relax a portion of the compressively strained pseudomorphic layer under the gate electrode and to cause tensile strain in a portion of the semiconductor channel layer located between the gate electrode and the pseudomorphic layer; and
re-growing the one or more sidewall spacers in the gate stack, so as to form a p-FET that contains source and drain formed by the first and second semiconductor structures and a channel formed by the tensilely strained portion of the semiconductor channel layer.

Preferably, the portion of the semiconductor channel layer located between the gate electrode and the pseudomorphic layer has a lateral half-width ranging from about 5 nm to about 50 nm. The thickness of the semiconductor channel layer preferably ranges from about 50 Å to about 150 Å, and more preferably from about 80 Å to about 120 Å.

In a further aspect, the present invention relates to a semiconductor device comprising at least one n-channel field effect transistor (n-FEF) located on a semiconductor substrate, wherein said n-FET comprises a source, a drain, a channel therebetween, and a gate stack that includes a gate dielectric layer, a gate electrode, and one or more sidewall spacers, wherein the channel of said n-FET is located in a tensilely strained semiconductor channel layer under the gate stack and above a pseudomorphic layer, and wherein the pseudomorphic layer is located atop the semiconductor substrate and has a lattice constant sufficiently larger than that of the semiconductor substrate to create compressive strain therein.

In one specific embodiment, the tensilely strained semiconductor channel layer and the pseudomorphic layer do not extend beyond the gate stack into the source and drain of the n-FET, and the source and drain of the n-FET are located directly on the semiconductor substrate.

In an alternative embodiment, the tensilely strained semiconductor channel layer and the pseudomorphic layer extend beyond the gate stack to under the source and drain of the n-FET, while the tensilely strained semiconductor channel layer and the pseudomorphic layer contain amorphization implants in regions underneath the sidewall spacers, which result in discontinuity in these layers.

Other aspects, features and advantages of the invention will be more fully apparent from the ensuing disclosure and appended claims.

### BRIEF DESCRIPTION OF THE DRAWINGS

FIG. 1 shows a cross-sectional view of an exemplary n-FET with a tensilely strained channel located under a gate stack and above a buried pseudomorphic layer, according to one embodiment of the present invention.

FIGS. 2A-2H are cross-sectional views that illustrate the processing steps for forming the n-FET of FIG. 1 with an adjacent p-FET having a channel that is essentially free of tensile strain, according to one embodiment of the present invention. The channel of the p-FET is located in a semiconductor substrate with no buried pseudomorphic layer thereunder.

FIGS. 3A-3G are cross-sectional views that illustrate the processing steps for forming the n-FET of FIG. 1 with an adjacent p-FET having a channel that is essentially free of tensile strain, according to one embodiment of the present invention. The channel of the p-FET is located in a semiconductor channel layer with a buried pseudomorphic layer thereunder.

FIG. 4 shows a cross-sectional view of an exemplary n-FET with a tensilely strained channel located in a semiconductor channel layer above a buried pseudomorphic layer, according to one embodiment of the present invention. Amorphization implants are present in the semiconductor channel layer and the buried pseudomorphic layer to cause discontinuity in these layers.

### DETAILED DESCRIPTION OF THE INVENTION AND PREFERRED EMBODIMENTS THEREOF

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It is well known that the lattice constant of germanium is about 4.2% greater than that of silicon, and that the lattice constant of a silicon-germanium alloy is linear with respect to its germanium concentration. A silicon-germanium layer that is epitaxially grown on a silicon substrate conforms to the lattice constant of the silicon and is therefore pseudomorphically strained. Because the lattice constant of germanium is larger than that of the silicon, the pseudomorphic silicon-germanium layer is compressively strained.

The present invention therefore proposes a method for using a buried pseudomorphic layer, which is located directly under the channel of an n-FET and is initially compressively strained, to induce or create the desired tensile strain in the channel of the n-FET to improve the device performance of the n-FET. The buried pseudomorphic layer can comprise any suitable semiconductor material that has a lattice constant sufficiently larger than that of the semiconductor substrate, so as to create compressive strain therein.

In order to achieve maximum tensile strain in the channel of the n-FET, the present invention further patterns the buried pseudomorphic layer and the overlaying semiconductor channel layer to allow maximum elastic relaxation of the compressively strained pseudomorphic layer.

It has been discovered that when the buried pseudomorphic layer and the overlaying semiconductor channel layer are patterned into small, isolated islands or mesa structures, elastic relaxation of the compressively strained pseudomorphic layer occurs, and the overlaying semiconductor channel layer becomes tensilely strained. More importantly, the amount of tensile strain created in the overlaying semiconductor channel layer depends on the lateral dimension of the island or mesa structures, and the highest tensile strain is found in islands or mesa structures of very small lateral dimensions.

Therefore, the present invention patterns the buried pseudomorphic layer and the overlaying semiconductor channel layer into islands or mesa structures by using the gate stacks of the n-FETs as masks. In this manner, the dimensions of the islands or mesa structures so formed are substantially the same as the gate lengths of the n-FETs, rather than the active areas of the n-FETs, thereby minimizing the dimensions of the islands or mesa structures. Further, the gate lengths of n-FETs have relatively small variations, typically on the order of about 7 nm, which will not lead to large performance variations for the resulting devices.

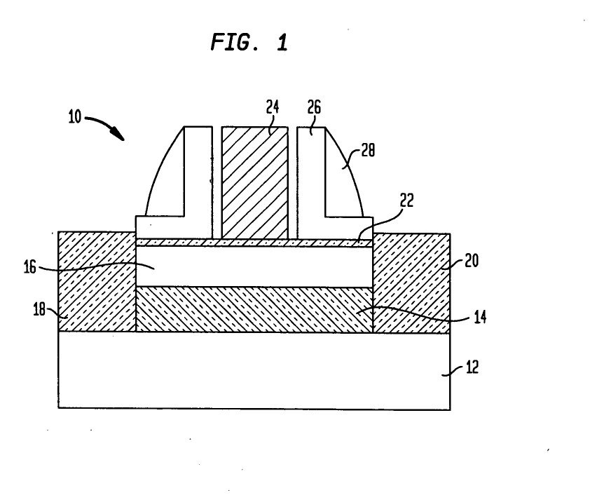

FIG. 1 illustratively shows a cross-sectional view of an exemplary n-FET, according to one embodiment of the present invention. Specifically, the n-FET 10 is formed over a semiconductor substrate 12 and contains a source 18, a drain 20, and a channel layer 16 that is located over a pseudomorphic layer 14. A gate stack that includes a gate dielectric layer 22, a gate electrode 24, a first sidewall spacer 26 (optional) and a second sidewall spacer 28 (optional) is provided over the channel 16. The buried pseudomorphic layer 14 contains compressive strain, and it is etched together with the channel layer 16 into an island or mesa structure that only extends under the gate stack, but not into the source and drain regions 18 and 20. In this manner, the compressively strained pseudomorphic layer 14 is at least partially relaxed and creates tensile strain in the channel layer 16, which functions to improve the device performance of the n-FET 10. The source and drain regions 18 and 20 are formed directly over the semiconductor substrate 12 after etching of the buried pseudomorphic layer 14 and the channel layer 16.

The island or mesa structure formed by the etched channel layer 16 and buried pseudomorphic layer 14 preferably has a dimension from about 5 nm to about 1 μm, more preferably from about 10 nm to about 50 nm, which allows sufficient relaxation of the compressively strained pseudomorphic layer 14 and creation of sufficient tensile strain in the channel layer 16.

The semiconductor substrate 12 may comprise any semiconductor material including, but not limited to: Si, SiC, SiGe, SiGeC, Ge alloys, GaAs, InAs, InP, as well as other III-V or II-VI compound semiconductors. Semiconductor substrate 12 may also comprise an organic semiconductor or a layered semiconductor such as Si/SiGe, a silicon-on-insulator (SOI) or a SiGe-on-insulator (SGOI). In some embodiments of the present invention, it is preferred that the semiconductor substrate 12 be composed of a Si-containing semiconductor material, i.e., a semiconductor material that includes silicon. The semiconductor substrate 12 may be doped, undoped or contain doped and undoped regions therein. Moreover, the semiconductor substrate 12 may be a hybrid substrate with device regions of different crystal orientations, which function to further improve the device performance of n-FET and p-FET devices.

The buried pseudomorphic layer 14 is grown epitaxially over the semiconductor substrate 12, and it may contain any suitable semiconductor material having a lattice constant sufficiently larger than that of the semiconductor substrate 12 in order to create compressive strain in layer 14.

Preferably, when the semiconductor substrate 12 is composed of silicon, the buried pseudomorphic layer 14 comprises silicon-germanium. It is important to note that when the strain in a pseudomorphically grown SiGe film reaches a critical level, either due to increase of the SiGe film thickness or increase of the Ge content, it can no longer be contained by elastic energy stored in the distorted SiGe crystal structure. Instead, a portion of the strain will be relaxed through generation of misfit dislocations in the heteroepitaxial interface. Therefore, for a SiGe film of a specific Ge content, there exists a “critical thickness,” defined as the maximum thickness for the pseudomorphic growth of the SiGe film, below which the strain caused by lattice mismatch between Si and Ge is contained by elastic energy stored in crystal lattice distortion, and above which a portion of the strain is relaxed through generation of misfit dislocations in the heteroepitaxial interface. Similarly, for a SiGe film of a specific thickness, there exists a “critical Ge content,” which is defined as the maximum germanium content that can be incorporated into the pseudomorphic SiGe film, below which the strain caused by lattice mismatch between Si and Ge is contained by elastic energy stored in crystal lattice distortion, and above which a portion of the strain is relaxed through generation of misfit dislocations in the heteroepitaxial interface. Because dislocation defects originated from strain relaxation are electrically active and can cause increased carrier scattering, carrier trapping, and carrier recombination, it is therefore important to maintain the Ge content and the thickness of the pseudomorphic SiGe layer 14 below the critical values, in order to avoid formation of dislocation defects in the device structure. The critical Ge content for a SiGe layer of a specific thickness can be readily determined by various known methods, which are not described in detail herein. Preferably, the buried pseudomorphic SiGe layer 14 has: (1) a thickness ranging from about 10 nm to about 1000 nm, more preferably from about 100 nm to about 500 nm, and most preferably from about 150 nm to about 250 nm, and (2) a Ge content ranging from about 5% to about 30%, more preferably from about 10% to about 20%.

The channel layer 16 is grown epitaxially over the buried pseudomorphic layer 14, and it may contain any suitable semiconductor material having a lattice constant sufficiently smaller than that of the buried pseudomorphic layer 14, so that when the buried pseudomorphic layer 14 is relaxed, sufficient tensile strain can be created in the channel layer 16 located thereabove. Preferably, the channel layer 16 comprises silicon when the buried pseudomorphic layer 14. More preferably, the channel layer 16 has a thickness ranging from about 50 Å to about 150 Å, and most preferably from about 80 Å to about 120 Å.

The source and drain regions 18 and 20 are epitaxially grown over the semiconductor substrate 12 at opposite sides of the island or mesa structure formed by etching of the buried pseudomorphic layer 14 and the channel layer 16. They may contain any suitable semiconductor material, including, but not limited to: Si, SiC, SiGe, SiGeC, Ge alloys, GaAs, InAs, InP, as well as other III-V or II-VI compound semiconductors. The source and drain regions 18 and 20 may also comprise an organic semiconductor or a layered semiconductor such as Si/SiGe, a silicon-on-insulator (SOI) or a SiGe-on-insulator (SGOI).

The source and drain regions 18 and 20 may incorporate any additional strain-inducing structure known in the art for applying tensile strain to the channel 16 of the n-FET 10. For example, the source and drain regions 18 and 20 may comprise tensilely stressed Si:C alloy, which applies additional tensile strain to the channel layer 16. For another example, source and drain regions 18 and 20 may comprise nitride liners that are located below the channel layer 16 to apply additional tensile strain to the channel layer 16. Further, a stress-inducing nitride liner can cover the entire n-FET 10 or at least a portion thereof for applying the desired tensile strain to the channel 16.

The high performance n-FETs of the present invention can be readily integrated with p-FETs in various ways to form CMOS devices. Since tensile strain in the channel regions may adversely impact the performance of the p-FETs, it is preferred to form p-FETs with channels that are essentially free of tensile strain. For example, such p-FETs can comprise channels that are formed either in conventional, unstrained semiconductor substrates, or in unstrained semiconductor layers that are located on un-relaxed and fully strained pseudomorphic layers.

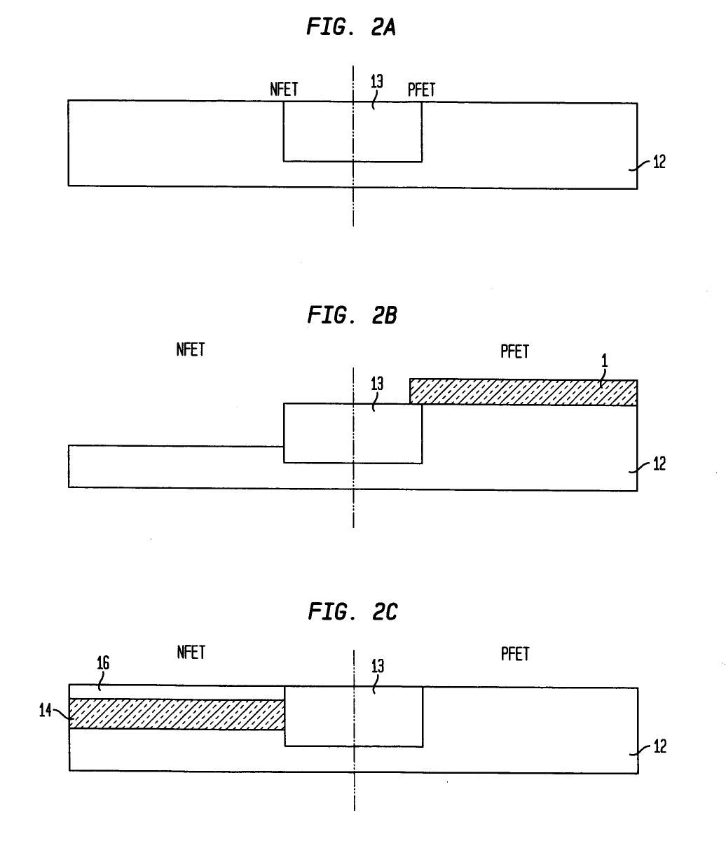

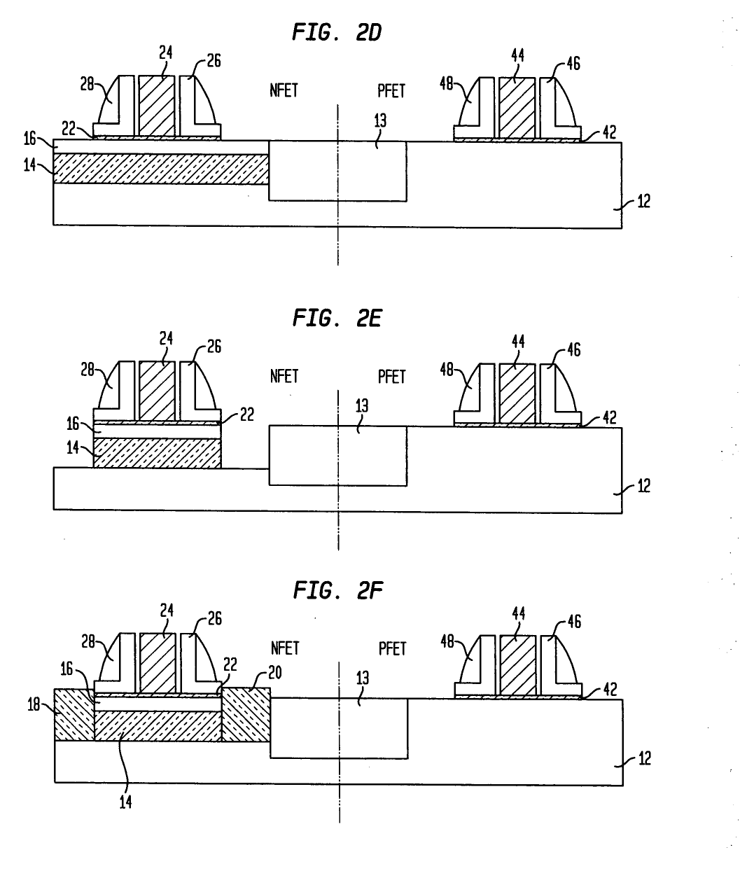

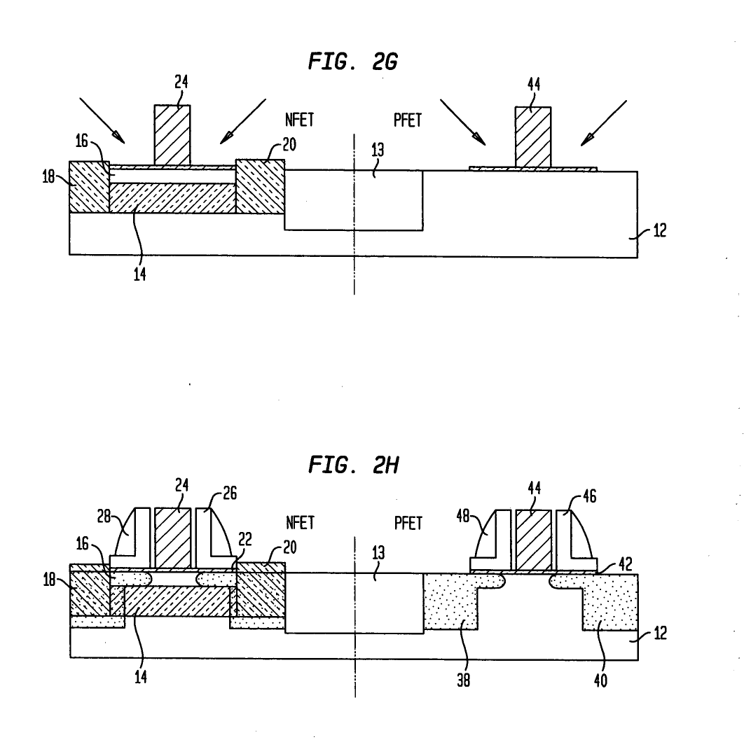

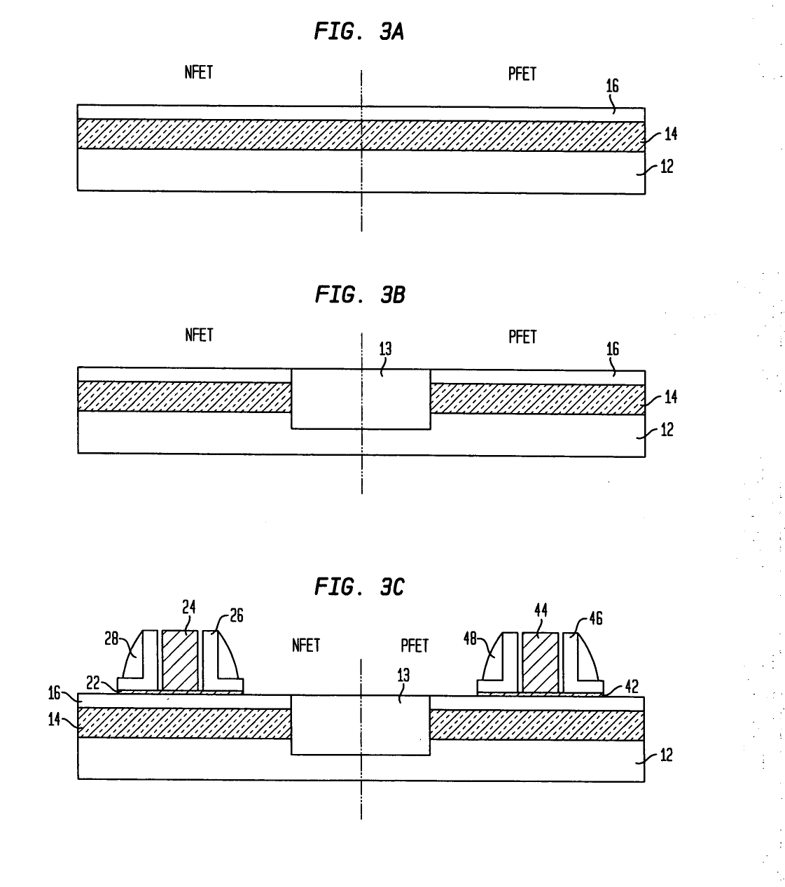

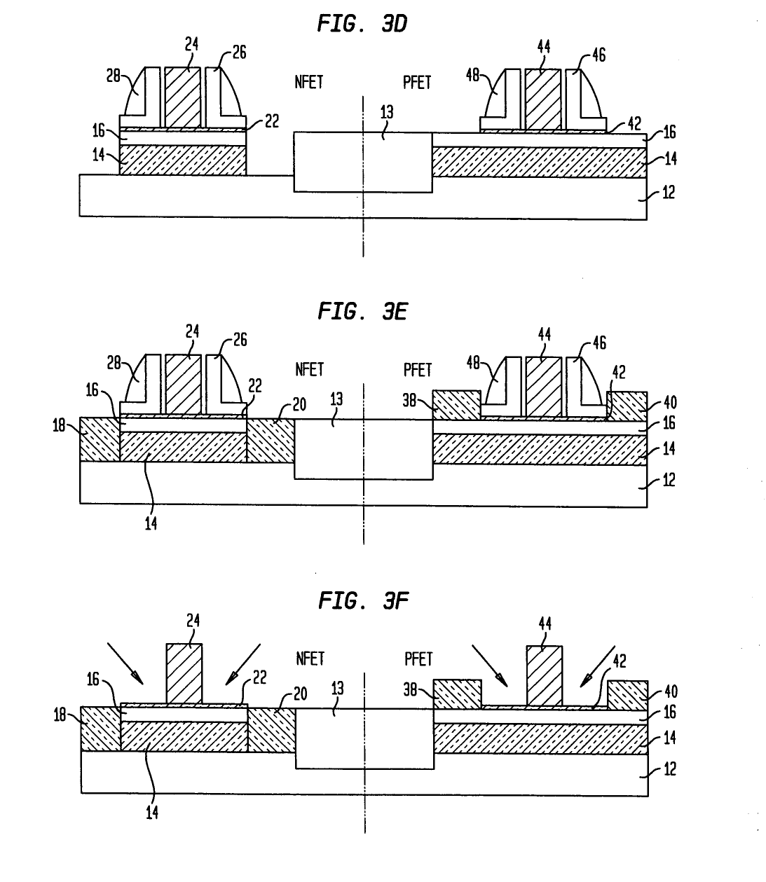

The processing steps that can be used for forming the CMOS devices with integrate n-FETs and p-FETs will now be described in greater detail by referring to the accompanying drawings in FIGS. 2A-3G. Note that in these drawings, which are not drawn to scale, like and/or corresponding elements are referred to by like reference numerals. It is further noted that in the drawings only one n-FET and one p-FET are shown atop a semiconductor substrate. Although illustration is made to such an embodiment, the present invention is not limited to the formation of any specific number of FET devices on the surface of the semiconductor structure.

Reference are first made to FIGS. 2A-2H, which illustrate exemplary processing steps for forming the n-FET of FIG. 1 with an adjacent p-FET having a channel that is located in an unstrained semiconductor substrate with no buried pseudomorphic SiGe layer thereunder, according to one embodiment of the present invention.

FIG. 2A first shows formation of at least one isolation region 13 in the semiconductor substrate 12, for isolating the n-FET and the p-FET. The isolation region 13 may be a trench isolation region or a field oxide isolation region. The trench isolation region is formed utilizing a conventional trench isolation process well known to those skilled in the art. For example, lithography, etching and filling of the trench with a trench dielectric may be used in forming the trench isolation region. Optionally, a liner may be formed in the trench prior to trench fill, a densification step may be performed after the trench fill and a planarization process may follow the trench fill as well. The field oxide may be formed utilizing a so-called local oxidation of silicon process.

After forming the at least one isolation region 13 within the semiconductor substrate 12, a patterned hard mask 1 is provided to selectively cover the p-FET device region. The semiconductor substrate 12 in the n-FET device region is then selective etched to form a recess therein, as shown in FIG. 2B. The patterned hard mask 1 may be an oxide, nitride, oxynitride or any combination thereof. Preferably, the hard mask 1 comprises silicon nitride.

Next, a pseudomorphic layer 14 is epitaxially grown over the recessed semiconductor substrate 12, followed by growth of a semiconductor channel layer 16 thereon, as shown in FIG. 2C. As described hereinabove, the pseudomorphic layer 14 contains any suitable semiconductor material having a lattice constant sufficiently larger than that of the semiconductor substrate 12 in order to create compressive strain in layer 14.

FIG. 2D shows the formation of an n-FET gate stack and a p-FET gate stack over the structure shown by FIG. 2C, using conventional CMOS techniques. Specifically, the n-FET gate stack comprises a gate dielectric layer 22, a gate electrode 24, and optional sidewall spacers 26 and 28. The p-FET similarly comprises a gate dielectric layer 42, a gate electrode 44, and optional sidewall spacers 46 and 48. The gate stacks may comprise additional structure layers, e.g., cap layers and/or diffusion barrier layers (not shown), as commonly included in MOS gate structures.

The gate dielectric layers 22 and 42 of the gate stacks are comprised of an insulating material including, but not limited to: an oxide, nitride, oxynitride and/or silicate including metal silicates and nitrided metal silicates. They can be formed by a thermal growing process such as, for example, oxidation, nitridation or oxynitridation. Alternatively, the gate dielectric layers 22 and 42 can be formed by a deposition process such as, for example, chemical vapor deposition (CVD), plasma-assisted CVD, atomic layer deposition (ALD), evaporation, reactive sputtering, chemical solution deposition and other like deposition processes.

The gate electrodes 24 and 44 of the gate stacks may comprise either doped or undoped polysilicon formed by deposition and etching. A reoxidation process can optionally, but not necessarily, be performed to create a conformal silicon oxide sidewall layer (not shown) over the patterned polysilicon gate stacks as mentioned hereinabove. Next, a conformal silicon nitride layer and a conformal silicon oxide layer is deposited over the entire structure, which can then be patterned to form sidewall nitride spacers 26, 46 and sidewall oxide spacers 28, 48 along exposed sidewalls of the gate stacks, as shown in FIG. 2D. Patterning of the conformal silicon nitride and silicon oxide layers can be readily achieved by utilizing known etching steps, which are not described in detail herein.

Subsequently, the n-FET device region is selectively etched by using the n-FET gate stack as a mask to remove portions of the semiconductor channel layer 16 and the buried pseudomorphic layer 14 that are not protected by the n-FET gate stack and to expose an upper surface of the recessed semiconductor substrate 12, as shown in FIG. 2E. In this manner, the semiconductor channel layer 16 and the buried pseudomorphic layer 14 are patterned to form an isolated island or mesa structure that extends only underneath the n-FET gate stack, which allows sufficient relaxation of the compressively strained pseudomorphic layer 14 and creation of sufficient tensile strain in the channel layer 16. The p-FET device is protected by photoresist during this etch.

Next, first and second semiconductor structures 18 and 20 are epitaxially grown on the exposed surface of the recessed semiconductor substrate 12 in the n-FET device region to form the source and drain of the n-FET, which have upper surfaces that are substantially coplanar with that of the channel layer 16, as shown in FIG. 2F. The p-FET areas have to be protected by a hard mask, such as, for example, silicon nitride, during this selective epitaxial growth. Alternatively, epitaxial growth can be performed in the p-FET areas as well, which will provide a p-FET with raised source/drain.

The source and drain 18 and 20 may comprise any additional strain-inducing structure (not shown) for applying tensile strain to the channel layer 16. For example, the source and drain 18 and 20 may comprise tensilely stressed Si:C alloy. In a preferred embodiment of the present invention, the source and drain 18 and 20 comprise nitride liners that are formed by first depositing a silicide metal (i.e., a metal that is capable of reacting with silicon to form metal silicide), annealing the silicide metal to form metal silicide layers, and then depositing nitride liners thereover. The nitride liners so formed function to add additional stress in the channel layer 16.

Subsequently, the sidewall spacers 26, 28, 46, and 48 of the n-FET and p-FET gate stacks are removed to allow extension and halo implantation, as shown in FIG. 2G, followed by re-growth of the sidewall spacers 26, 28, 46, and 48, source/drain implantation and silicidation, as shown in FIG. 2H. The processing steps for the spacer removal/re-growth, the extension/halo implantation, the source/drain implantation, and the silicidation are well known in the art and are therefore not described in detail herein.

FIGS. 3A-3H illustrate alternative processing steps for forming the n-FET of FIG. 1 with an adjacent p-FET that contains a channel located in an strained semiconductor channel layer with a un-relaxed, fully strained pseudomorphic layer thereunder, according to one embodiment of the present invention.

FIG. 3A first shows epitaxial growth of a pseudomorphic layer 14 over a semiconductor substrate 12, followed by growth of a semiconductor channel layer 16 thereon. As described hereinabove, the pseudomorphic layer 14 contains any suitable semiconductor material having a lattice constant sufficiently larger than that of the semiconductor substrate 12 in order to create compressive strain in layer 14.

FIG. 3B shows formation of at least one isolation region 13 that extends through the semiconductor channel layer 16 and the buried pseudomorphic layer 14 into the semiconductor substrate 12, for isolating the n-FET and the p-FET device regions.

After forming the at least one isolation region 13, an n-FET gate stack and a p-FET gate stack are formed over the n-FET and p-FET device regions, as shown in FIG. 3C, by using conventional CMOS techniques. Specifically, the n-FET gate stack comprises a gate dielectric layer 22, a gate electrode 24, and optional sidewall spacers 26 and 28. The p-FET similarly comprises a gate dielectric layer 42, a gate electrode 44, and optional sidewall spacers 46 and 48. As mentioned hereinabove, the gate stacks may comprise additional structure layers, e.g., cap layers and/or diffusion barrier layers (not shown), as commonly included in MOS gate structures.

Subsequently, the n-FET device region is selectively etched by using the n-FET gate stack as a mask to remove portions of the semiconductor channel layer 16 and the buried pseudomorphic layer 14 in the n-FET device region not protected by the n-FET gate stack, thereby exposing an upper surface of the semiconductor substrate 12, as shown in FIG. 3D. At the same time, the p-FET device region is protected from the etching, so the semiconductor channel layer 16 and the buried pseudomorphic layer 14 in the p-FET device region are not removed at all. In this manner, the semiconductor channel layer 16 and the buried pseudomorphic layer 14 in the n-FET device region are patterned to form an isolated island or mesa structure in the n-FET device region, which extends only underneath the n-FET gate stack. The compressively strained pseudomorphic layer 14 in the island or mesa structure formed in the n-FET device region can at least be partially relaxed to create sufficient tensile strain in the channel layer 16 located thereabove.

Next, first and second semiconductor structures 18 and 20 are epitaxially grown on the exposed surface of the semiconductor substrate 12 in the n-FET device region to form the source and drain of the n-FET, which have upper surfaces that are substantially coplanar with that of the channel layer 16, as shown in FIG. 3E. Concurrently, first and second semiconductor structures 38 and 40 are epitaxially grown directly on the semiconductor channel layer 16 in the p-FET device region at opposite sides of the p-FET gate stack to form the source and drain of the p-FET, which are significantly raised in relation to the semiconductor channel layer 16 (as shown in FIG. 3E) and are therefore referred to hereinafter as the “raised” source/drain.

Subsequently, the sidewall spacers 26, 28, 46, and 48 of the n-FET and p-FET gate stacks are removed to allow extension and halo implantation, as shown in FIG. 3F, followed by re-growth of the sidewall spacers 26, 28, 46, and 48, source/drain implantation and silicidation, as shown in FIG. 3G, to complete the n-FET and p-FET devices.

In addition to the etching or patterning process described hereinabove, the buried pseudomorphic layer 16 can further be relaxed by an amorphization process, which introduces amorphization implants into the buried pseudomorphic layer 16 and results in a highly defective polycrystalline re-crystallized region, thereby creating discontinuity in layer 16 to allow relaxation of the layer 16.

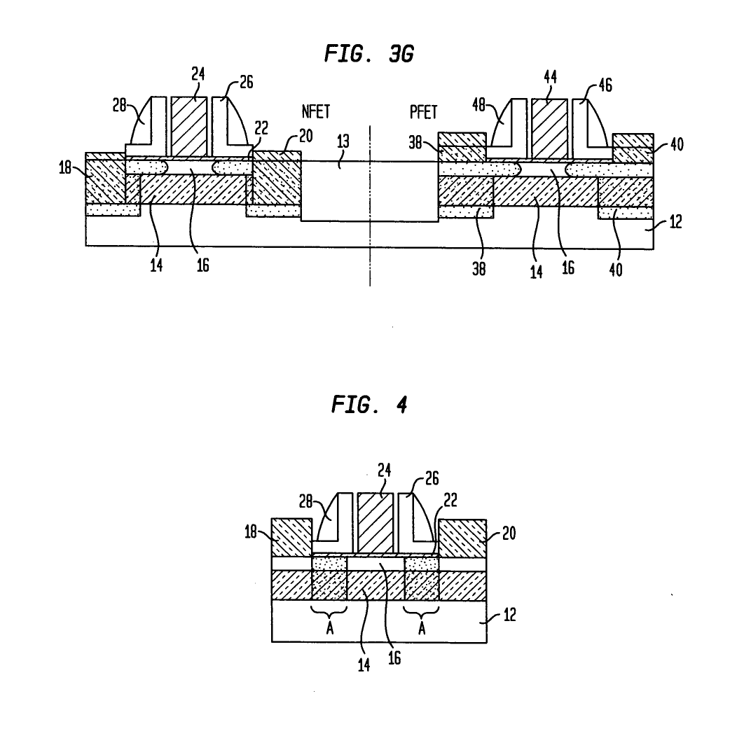

For example, FIG. 4 shows an n-FET that is formed over the unetched or un-patterned semiconductor channel layer 16 and buried pseudomorphic layer 14. Regions A of the unetched or un-patterned semiconductor channel layer 16 and buried pseudomorphic layer 14, however, contain amorphization implants, such as Ge, Ar, etc., which creates discontinuity in the unetched or un-patterned semiconductor channel layer 16 and buried pseudomorphic layer 14. Such discontinuity allows sufficient relaxation of the compressively strained pseudomorphic layer 14 and creation of sufficient tensile strain in the channel layer 16.

The n-FET structure shown in FIG. 4 can be readily formed by first epitaxially growing the pseudomorphic layer 14 and the semiconductor channel layer 16 over the semiconductor substrate 12, followed by: (1) formation of an n-FET gate stack that comprises the gate dielectric layer 22, the gate electrode 24, and optional sidewall spacers 26 and 28; (2) epitaxial growth of the raised source and drain 18 and 20 over the semiconductor channel layer 16 at opposite sides of the n-FET gate stack; (3) removal of the sidewall spacers 26 and 28 to introduce amorphization implants into the channel layer 16 and the pseudomorphic layer 14; (4) extension/halo implantation; (5) re-growth of the sidewall spacers 26 and 28, (5) source/drain implantation, and (6) source/drain silicidation. The processing steps for forming the above-described structures are well known in the art and are therefore not described in detail herein.

It should be noted that the methods of the present invention can be widely used for fabricating various semiconductor device structures, including, but not limited to, complementary metal-oxide-semiconductor (CMOS) transistors, as well as integrated circuit, microprocessors and other electronic devices comprising such CMOS transistors, which are well known to those skilled in the art and can be readily modified to incorporate the strained semiconductor-on-insulator structure of the present invention, and therefore details concerning their fabrication are not provided herein.

While the invention has been described herein with reference to specific embodiments, features and aspects, it will be recognized that the invention is not thus limited, but rather extends in utility to other modifications, variations, applications, and embodiments, and accordingly all such other modifications, variations, applications, and embodiments are to be regarded as being within the spirit and scope of the invention.

What is claimed is:

1. A method for fabricating a semiconductor device that comprises at least one n-channel field effect transistor (n-FET), said method comprising:
forming a pseudomorphic layer over a semiconductor substrate, wherein the pseudomorphic layer has a lattice constant sufficiently larger than that of the semiconductor substrate to create compressive strain therein;
forming a semiconductor channel layer over the pseudomorphic layer;
forming a gate stack over the semiconductor channel layer;
patterning a portion of the semiconductor channel layer and the pseudomorphic layer using the gate stack as a mask to form at least one mesa structure, in which the compressively strained pseudomorphic layer is at least partially relaxed to cause tensile strain in the semiconductor channel layer located thereabove; and epitaxially growing first and second semiconductor structures at opposite sides of the mesa structure to form an n-FET that contains a source and a drain formed by the first and second semiconductor structures and a channel formed by the tensilely strained semiconductor channel layer in the mesa structure.

2. The method of claim 1, wherein the mesa structure has a lateral half-width ranging from about 5 nm to about 1 μm.

3. The method of claim 1, wherein the semiconductor channel layer has a thickness ranging from about 50 Å to about 150 Å.

4. The method of claim 1, wherein the semiconductor channel layer has a thickness ranging from about 80 Å to about 120 Å.

5. The method of claim 1, wherein the semiconductor channel layer comprises silicon, and wherein the pseudomorphic layer comprises SiGe.

6. The method of claim 1, wherein the semiconductor substrate comprises a bulk semiconductor substrate.

7. The method of claim 1, wherein the semiconductor substrate comprises a semiconductor-on-insulator (SOI) structure.

8. The method of claim 1, wherein the first and second semiconductor structures comprise tensilely strained Si:C alloy for applying additional tensile strain to the channel of the n-FET.

9. The method of claim 1, wherein tensilely strained silicon nitride liners are formed at the opposite sides of the mesa structure before growth of the first and second semiconductor structures, and wherein said tensilely strained silicon nitride liners apply additional tensile strain to the channel of the n-FET.

10. The method of claim 1, wherein at least one p-channel field effect transistor (p-FET) is formed adjacent to the n-FET, wherein the semiconductor channel layer and the pseudomorphic layer do not extend into said p-FET, wherein said p-FET comprises a source, a drain, and a channel that are all located in the semiconductor substrate with a gate stack located on the channel, and wherein the channel is essentially free of tensile strain.

11. The method of claim 1, wherein at least one p-channel field effect transistor (p-FET) is formed adjacent to the n-FET, wherein the semiconductor channel layer and the pseudomorphic layer extend into said p-FET, wherein said p-FET comprises a channel that is formed by an un-patterned and continuous portion of the semiconductor channel layer and is essentially free of tensile strain, with a raised source and a raised drain located on the semiconductor channel layer at opposite sides of the channel and a gate stack located on the channel.

12. A method for fabricating a semiconductor device that comprises at least one n-channel field effect transistor (n-FET), said method comprising:
forming a pseudomorphic layer over a semiconductor substrate, wherein the pseudomorphic layer has a lattice constant sufficiently larger than that of the semiconductor substrate to create compressive strain therein;
forming a semiconductor channel layer over the pseudomorphic layer;
forming a gate stack over the semiconductor channel layer;
epitaxially growing first and second semiconductor structures at opposite sides of the gate stack;
removing the one or more sidewall spacers from the gate stack;
introducing amorphization implants into the semiconductor channel layer and the pseudomorphic layer through openings formed by removal of the sidewall spacers, wherein the amorphization implants break continuity of the semiconductor channel layer and the pseudomorphic layer to at least partially relax a portion of the compressively strained pseudomorphic layer under the gate electrode and to cause tensile strain in a portion of the semiconductor channel layer located between the gate electrode and the pseudomorphic layer; and
re-growing the one or more sidewall spacers in the gate stack, so as to form a p-FET that contains source and drain formed by the first and second semiconductor structures and a channel formed by the tensilely strained portion of the semiconductor channel layer.

13. The method of claim 12, wherein the portion of the semiconductor channel layer located between the gate electrode and the pseudomorphic layer has a lateral half-width ranging from about 5 nm to about 50 nm.

14. The method of claim 12, wherein the semiconductor channel layer has a thickness ranging from about 50 Å to about 150 Å.

15. The method of claim 12, wherein the semiconductor channel layer comprises silicon, and wherein the pseudomorphic layer comprises SiGe.

16. The method of claim 12, wherein the semiconductor substrate comprises a bulk semiconductor substrate or a semiconductor-on-insulator (SOI) structure.

17. The method of claim 12, wherein the first and second semiconductor structures comprise tensilely strained Si:C alloy for applying additional tensile strain to the channel of the n-FET.

18. A semiconductor device comprising at least one n-channel field effect transistor (n-FET) located on a semiconductor substrate, wherein said n-FET comprises a source, a drain, a channel therebetween, and a gate stack, wherein the channel of said n-FET is located in a tensilely strained semiconductor channel layer under the gate stack and above a pseudomorphic layer, and wherein the pseudomorphic layer is located atop the semiconductor substrate and has a lattice constant sufficiently larger than that of the semiconductor substrate to create compressive strain therein.

19. The semiconductor device of claim 18, wherein the tensilely strained semiconductor channel layer and the pseudomorphic layer do not extend beyond the gate stack into the source and drain of said n-FEF, and wherein the source and drain of the n-FET are located directly on the semiconductor substrate.

20. The semiconductor device of claim 18, wherein the tensilely strained semiconductor channel layer and the pseudomorphic layer extend beyond the gate stack to under the source and drain of said n-FET, and wherein the tensilely strained semiconductor channel layer and the pseudomorphic layer contain amorphization implants in regions underneath the sidewall spacers, which result in discontinuity in said layers.
